(19) United States
(12) Patent Application Publication
(10) Pub. No.: US 2025/0204156 A1
(43) Pub. Date: Jun. 19, 2025

(54) SUB-PIXEL STRUCTURE, DISPLAY PANEL AND PREPARATION METHOD THEREOF

(71) Applicant: Hefei Visionox Technology Co., Ltd., Hefei (CN)

(72) Inventors: Bo XIA, Hefei (CN); Guangyuan SUN, Hefei (CN); Pei DUAN, Hefei (CN); Miaomiao TIAN, Hefei (CN); Zhili MA, Hefei (CN)

(73) Assignee: Hefei Visionox Technology Co., Ltd., Hefei (CN)

(21) Appl. No.: 19/067,996

(22) Filed: Mar. 3, 2025

Related U.S. Application Data
(63) Continuation of application No. PCT/CN2023/135327, filed on Nov. 30, 2023.

(30) Foreign Application Priority Data
Jun. 26, 2023 (CN) 202310771428.5

(51) Int. Cl. H10K 59/121; H10K 59/12; H10K 59/131

(52) U.S. Cl. CPC H10K 59/1213; H10K 59/1201; H10K 59/1216; H10K 59/131

(57) ABSTRACT

Provided are a sub-pixel structure, a display panel, a preparation method thereof and a display device. The sub-pixel structure includes a first sub-portion, a second sub-portion, a third sub-portion, a fourth sub-portion and a fifth sub-portion. The first sub-portion and the second sub-portion are arranged along a first direction. The third sub-portion, the first sub-portion and the fourth sub-portion are arranged along a second direction sequentially. The second direction intersects the first direction. The fifth sub-portion and the fourth sub-portion are parallel in the first direction. The second sub-portion and the fifth sub-portion are parallel in the second direction. A storage capacitor is disposed within the first sub-portion. A drive transistor and switch transistors are disposed within other sub-portions.

This application is a continuation of International Patent Application No. PCT/CN2023/135327, filed on Nov. 30, 2023, which claims priority to Chinese Patent Application No. 202310771428.5 filed on Jun. 26, 2023, disclosures of both of which are incorporated herein by reference in their entireties.

### FIELD

The present application relates to the field of display technology, for example, a sub-pixel structure, a display panel and a preparation method thereof.

### BACKGROUND

Display panels have been widely applied in all aspects of production and life such as computer displays, mobile phones, tablet computers, wearable devices, robot displays, billboards, floor indexes of shopping malls, service terminals in public places and robotic arm teach pendants. A display panel is formed by thousands of sub-pixels. A design manner of the thousands of sub-pixels plays a decisive role in aspects of the display panel such as a high resolution, light transmittance, a leakage current. For example, a display panel of a self-luminous device such as an organic light-emitting diode has a complex sub-pixel structure, causing the performance of the display panel not to be optimal yet. There is still room for optimization of sub-pixels in the related art.

### SUMMARY

The present application provides a sub-pixel structure, a display panel and a preparation method thereof to optimize the sub-pixel structure, improving the performance of the display panel.

Embodiments of the present application provide the solutions below.

A sub-pixel structure is provided. The sub-pixel structure includes a first sub-portion, a second sub-portion, a third sub-portion, a fourth sub-portion and a fifth sub-portion.

The first sub-portion and the second sub-portion are arranged along a first direction; the third sub-portion, the first sub-portion and the fourth sub-portion are arranged along a second direction sequentially; and the second direction intersects the first direction.

The fifth sub-portion and the fourth sub-portion are parallel in the first direction; and the second sub-portion and the fifth sub-portion are parallel in the second direction.

A storage capacitor is disposed within the first sub-portion, a drive transistor and at least one switch transistor connected to a control terminal of the drive transistor are disposed within the second sub-portion, at least one switch transistor connected to a first electrode of the drive transistor is disposed within the third sub-portion, at least one switch transistor connected to the storage capacitor is disposed within the fourth sub-portion, and at least one switch transistor connected to a second electrode of the drive transistor is disposed within the fifth sub-portion.

Correspondingly, the present application further provides a display panel including a plurality of sub-pixel structures according to any embodiment of the present application.

Correspondingly, the present application further provides a preparation method for a display panel. The method includes the steps below.

A base is divided into a plurality of sub-pixel regions, and the plurality of sub-pixel regions are divided into a first sub-portion, a second sub-portion, a third sub-portion, a fourth sub-portion and a fifth sub-portion, where the first sub-portion and the second sub-portion are arranged along a first direction; the third sub-portion, the first sub-portion and the fourth sub-portion are arranged along a second direction sequentially; the second direction intersects the first direction; the fifth sub-portion and the fourth sub-portion are parallel in the first direction; and the second sub-portion and the fifth sub-portion are parallel in the second direction.

A storage capacitor is formed within the first sub-portion, a drive transistor and at least one switch transistor connected to a control terminal of the drive transistor are formed within the second sub-portion, at least one switch transistor connected to a first electrode of the drive transistor is formed within the third sub-portion, at least one switch transistor connected to the storage capacitor is formed within the fourth sub-portion, and at least one switch transistor connected to a second electrode of the drive transistor is formed within the fifth sub-portion.

In the embodiments of the present application, sub-pixels are divided into five sub-portions, and devices in the five sub-portions are arranged according to the preceding set rules and the layout of the sub-pixels can be compact, to facilitate a reduction in the layout space of the sub-pixels and facilitating the high-density arrangement of the display panel. The storage capacitor is disposed within the first sub-portion, and the drive transistor is disposed within the second sub-portion and a long wire connecting the storage capacitor and the drive transistor cannot be required, to enable a tight connection. Moreover, only the storage capacitor is disposed within the first sub-portion and signal lines such as a scan line and a light emission control line cannot be disposed within the first sub-portion, to reduce crosstalk caused by the signal lines to the storage capacitor. In conclusion, in the embodiments of the present application, the sub-pixel structure is optimized and the performance of the display panel can be improved.

### BRIEF DESCRIPTION OF DRAWINGS

FIG. 1 is a diagram illustrating a sub-pixel structure according to an embodiment of the present application.

FIG. 2 is a diagram illustrating the structure of a pixel circuit according to an embodiment of the present application.

FIG. 3 is a diagram illustrating another sub-pixel structure according to an embodiment of the present application.

FIG. 4 is a diagram illustrating yet another sub-pixel structure according to an embodiment of the present application.

FIG. 5 is a diagram illustrating the structure of FIG. 3 taken along an A-A section.

FIG. 6 is an enlarged diagram illustrating the structure of a first sub-portion and a second sub-portion according to an embodiment of the present application.

FIG. 7 is a diagram illustrating the structure of FIG. 6 taken along a B-B section.

FIG. 8 is an equivalent circuit diagram of a drive transistor of FIG. 6.

FIG. 9 is an enlarged diagram illustrating the structure of another first sub-portion and another second sub-portion according to an embodiment of the present application.

FIG. 10 is a diagram illustrating the structure of FIG. 9 taken along a C-C section.

FIG. 11 is an equivalent circuit diagram of a drive transistor of FIG. 9.

FIG. 12 is a diagram illustrating yet another sub-pixel structure according to an embodiment of the present application.

FIG. 13 is a section diagram illustrating yet another sub-pixel structure according to an embodiment of the present application.

FIG. 14 is a diagram illustrating the patterned structure of a semiconductor layer according to an embodiment of the present application.

FIG. 15 is a diagram illustrating the patterned structure of a first wire layer according to an embodiment of the present application.

FIG. 16 is a diagram illustrating the patterned structure of a second wire layer according to an embodiment of the present application.

FIG. 17 is a diagram illustrating the patterned structure of a gate layer according to an embodiment of the present application.

FIG. 18 is a diagram illustrating the patterned structure of a third wire layer according to an embodiment of the present application.

FIG. 19 is a diagram illustrating the patterned structure of first-type vias and second-type vias according to an embodiment of the present application.

FIG. 20 is a diagram illustrating the patterned structure of third-type vias and fourth-type vias according to an embodiment of the present application.

FIG. 21 is a diagram illustrating the patterned structure of a fourth wire layer according to an embodiment of the present application.

FIG. 22 is a diagram illustrating the patterned structure of fifth-type vias according to an embodiment of the present application.

FIG. 23 is a diagram illustrating the patterned structure of sixth-type vias according to an embodiment of the present application.

FIG. 24 is a section diagram illustrating the structure of yet another sub-pixel structure according to an embodiment of the present application.

FIG. 25 is a diagram illustrating the patterned structure of another semiconductor layer according to an embodiment of the present application.

### DETAILED DESCRIPTION

It is to be noted that the terms such as “first” and “second” in the description, claims and drawings of the present application are used for distinguishing between similar objects and are not necessarily used for describing a particular order or sequence. It is to be understood that data used in this manner is interchangeable in appropriate cases and the embodiments of the present application described herein can also be implemented in an order not illustrated or described herein. In addition, the terms “including”, “having” and any variations thereof are intended to encompass a non-exclusive inclusion. For example, a process, method, system, product, or device that includes a series of steps or units may include not only the expressly listed steps or units but also other steps or units that are not expressly listed or are inherent to such a process, method, system, product, or device.

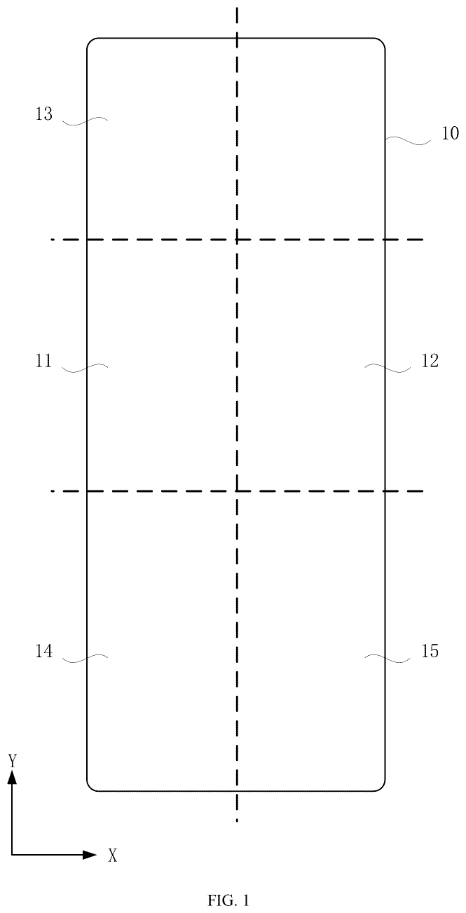

An embodiment of the present application provides a sub-pixel structure. Sub-pixels provided in the embodiment of the present application have the layout region re-divided. FIG. 1 is a diagram illustrating a sub-pixel structure according to an embodiment of the present application. Referring to FIG. 1, the sub-pixel structure 10 includes a first sub-portion 11, a second sub-portion 12, a third sub-portion 13, a fourth sub-portion 14 and a fifth sub-portion 15.

Using the first sub-portion 11 as the reference, a first direction X intersects a second direction Y. Exemplarily, the first direction X is perpendicular to the second direction Y. The first sub-portion 11 and the second sub-portion 12 are arranged along the first direction X. The third sub-portion 13, the first sub-portion 11 and the fourth sub-portion 14 are arranged along the second direction Y sequentially. The fifth sub-portion 15 and the fourth sub-portion 14 are parallel in the first direction X. The second sub-portion 12 and the fifth sub-portion 15 are parallel in the second direction Y.

A sub-pixel is formed by pixel circuits. A pixel circuit is formed by devices such as a storage capacitor, a drive transistor and a switch transistor. A storage capacitor is disposed within the first sub-portion 11. A drive transistor and at least one switch transistor connected to a control terminal of the drive transistor are disposed within the second sub-portion 12. At least one switch transistor connected to a first electrode of the drive transistor is disposed within the third sub-portion 13. At least one switch transistor connected to the storage capacitor is disposed within the fourth sub-portion 14. At least one switch transistor connected to a second electrode of the drive transistor is disposed within the fifth sub-portion 15.

In the embodiment of the present application, the sub-pixels are divided into five sub-portions, and devices in the five sub-portions are arranged according to the preceding set rules and the layout of the sub-pixels can be compact, to facilitate a reduction in the layout space of the sub-pixels and facilitating the high-density arrangement of a display panel. The storage capacitor is disposed within the first sub-portion 11, and the drive transistor is disposed within the second sub-portion 12 and a long wire connecting the storage capacitor and the drive transistor cannot be required, to enable a tight connection. Moreover, only the storage capacitor is disposed within the first sub-portion 11 and signal lines such as a scan line and a light emission control line cannot be disposed within the first sub-portion 11, to reduce crosstalk caused by the signal lines to the storage capacitor and and signal lines such as a scan line and a light emission control line cannot be disposed within the second sub-portion 12, to reduce crosstalk caused by the signal lines to the drive transistor DT. In conclusion, in the embodiment of the present application, the sub-pixel structure 10 is optimized and the performance of the display panel can be improved.

Based on the preceding embodiment, for different types of the pixels circuits, arrangement manners of the sub-pixel structure are also different, which is described in detail below but does not limit the present application.

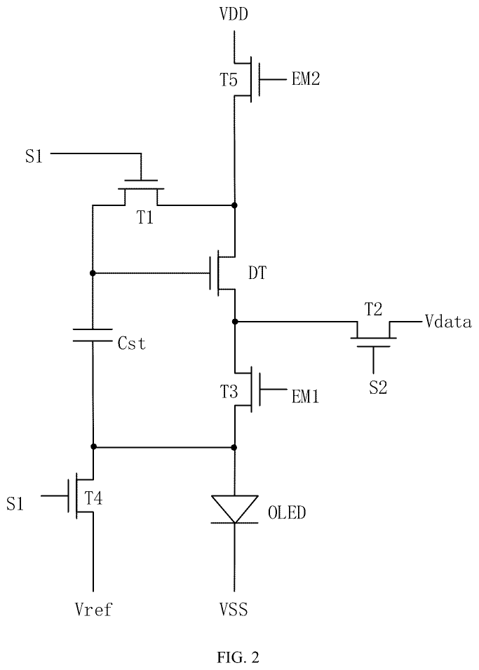

FIG. 2 is a diagram illustrating the structure of a pixel circuit according to an embodiment of the present application. Referring to FIG. 2, in an embodiment of the present application, exemplarily, the pixel circuit includes six transistors and one storage capacitor Cst. The connection relationship between the six transistors and the storage capacitor Cst is described below.

The drive transistor DT is configured to generate a drive current in response to a data signal. Since the drive transistor DT is required to generate the drive current, the size of the drive transistor DT is greater than the size of another transistor.

A gate of a first switch transistor T1 is electrically connected to a first scan line S1, a first electrode of the first switch transistor T1 is electrically connected to a gate of the drive transistor DT, and a second electrode of the first switch transistor T1 is electrically connected to the second electrode of the drive transistor DT. The first switch transistor T1 is configured to transmit the data signal from the second electrode of the drive transistor DT to the gate of the drive transistor DT in the data write stage to fulfill the threshold compensation function of the drive transistor, so the first switch transistor T1 may be referred to as a compensation transistor.

A gate of a second switch transistor T2 is electrically connected to a second scan line S2, a first electrode of the second switch transistor T2 is electrically connected to a data line Vdata, and a second electrode of the second switch transistor T2 is electrically connected to the first electrode of the drive transistor DT. The second switch transistor T2 is configured to transmit the data signal and write the data signal to the first electrode of the drive transistor DT, so the second switch transistor T2 may be referred to as a data write transistor.

A gate of a third switch transistor T3 is electrically connected to a first light emission control line EM1, a first electrode of the third switch transistor T3 is electrically connected to the first electrode of the drive transistor DT, and a second electrode of the third switch transistor T3 is electrically connected to the storage capacitor Cst. The second electrode of the third switch transistor T3 is further configured to connect a light-emitting device OLED. The third switch transistor T3 serves as a transistor between the drive transistor DT and the light-emitting device OLED. The light-emitting device OLED can emit light only when the third switch transistor T3 is turned on, so the third switch transistor T3 may be referred to as a light emission control transistor.

A gate of a fourth switch transistor T4 is electrically connected to the first scan line S1, a first electrode of the fourth switch transistor T4 is electrically connected to a reference voltage line Vref, and a second electrode of the fourth switch transistor T4 is electrically connected to the second electrode of the third switch transistor T3. The second electrode of the fourth switch transistor T4 is further configured to connect the light-emitting device OLED and the storage capacitor Cst. The fourth switch transistor T4 can transmit a reference voltage signal to the light-emitting device OLED and the storage capacitor Cst and the light-emitting device OLED and the storage capacitor Cst can be initialized. Therefore, the fourth switch transistor T4 may be referred to as a reset transistor.

A gate of a fifth switch transistor T5 is electrically connected to a second light emission control line EM2, a first electrode of the fifth switch transistor T5 is electrically connected to a power line VDD, and a second electrode of the fifth switch transistor T5 is electrically connected to the second electrode of the drive transistor DT. In one embodiment, the functions of the fifth switch transistor T5 are similar to those of the third switch transistor T3, and the light-emitting device OLED can emit light in the light emission stage only when both the third switch transistor T3 and the fifth switch transistor T5 are turned on, so the fifth switch transistor T5 may also be referred to as a light emission control transistor. In another embodiment, when all the fifth switch transistor T5, the first switch transistor T1 and the fourth switch transistor T4 are turned on in the initialization stage, the storage capacitor Cst can be initialized.

According to the structure of the preceding pixel circuit, an embodiment of the present application further provides a specific sub-pixel structure that is described below but does not limit the present application.

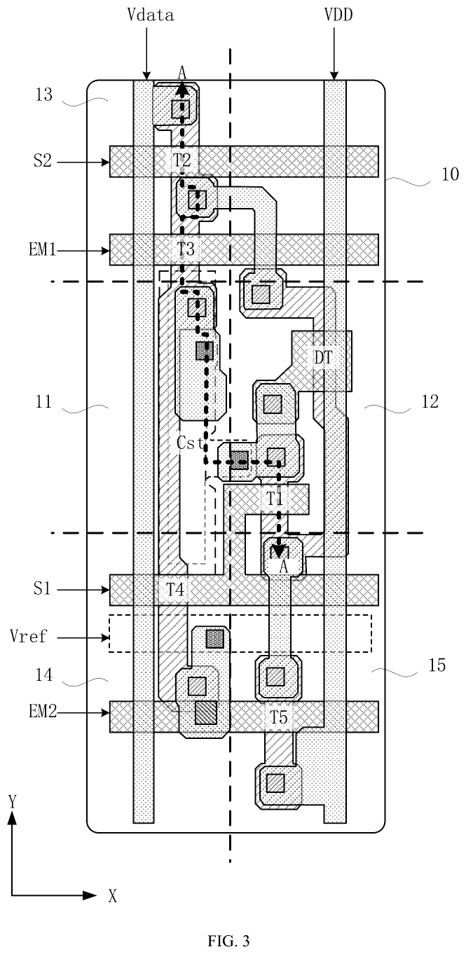

FIG. 3 is a diagram illustrating another sub-pixel structure according to an embodiment of the present application. In conjunction with FIGS. 2 and 3, in an embodiment of the present application, exemplarily, the storage capacitor Cst is disposed within the first sub-portion 11; the drive transistor DT and the first switch transistor T1 are disposed within the second sub-portion 12; the second switch transistor T2 and the third switch transistor T3 are disposed within the third sub-portion 13; the fourth switch transistor T4 is disposed within the fourth sub-portion 14; and the fifth switch transistor T5 is disposed within the fifth sub-portion 15. In the embodiment of the present application, this configuration can reduce the length of a connection wire between transistors and the arrangement of the sub-pixels can be compact easily.

In conjunction with FIGS. 2 and 3, in an embodiment of the present application, exemplarily, all the second scan line S2, the first light emission control line EM1, the first scan line S1 and the second light emission control line EM2 extend along the first direction X. The second scan line S2 and the first light emission control line EM1 are connected to the third sub-portion 13, the first scan line S1 is connected to the fourth sub-portion 14, and the second light emission control line EM2 is connected to the fifth sub-portion 15. This configuration can make it easier for the second scan line S2 to supply a second scan signal to the second switch transistor T2, for the first light emission control line EM1 to supply a first light emission control signal to the third switch transistor T3, for the first scan line S1 to supply a first scan signal to the fourth switch transistor T4 and the first switch transistor T1 and for the second light emission control line EM2 to supply a second light emission control signal to the fifth switch transistor T5.

In conjunction with FIGS. 2 and 3, exemplarily, the second scan line S2, the first light emission control line EM1, the first scan line S1 and the second light emission control line EM2 are arranged in the second direction Y sequentially. Exemplarily, in FIG. 3, the second scan line S2 is located above the first light emission control line EM1 and the second switch transistor T2 can be easily disposed above the third switch transistor T3, to make it easier to directly connect the third switch transistor T3 to the storage capacitor Cst. Similarly, the first scan line S1 is located above the second light emission control line EM2 and the fourth switch transistor T4 can be easily disposed above the fifth switch transistor T5, to make it easier to directly connect the fourth switch transistor T4 to the storage capacitor Cst.

It is to be noted that in other embodiments, the second scan line S2 may also be disposed below the first light emission control line EM1, or the first scan line S1 may also be disposed below the second light emission control line EM2. This is not limited in the present application.

In conjunction with FIGS. 2 and 3, in an embodiment of the present application, exemplarily, both the data line Vdata and the power line VDD extend along the second direction Y, the data line Vdata is connected to the third sub-portion 13, the first sub-portion 11 and the fourth sub-portion 14, and the power line VDD is connected to the second sub-portion 12 and the fifth sub-portion 15. The second switch transistor T2 is disposed within the third sub-portion 13, the data line Vdata is connected to the third sub-portion 13 and the data line Vdata can easily supply the data signal to the second switch transistor T2, and, in addition, since the data line Vdata is shared in the second direction Y, the first sub-portion 11 and the fourth sub-portion 14 are also required to be connected. Similarly, the fifth switch transistor T5 is disposed within the fifth sub-portion 15, the power line VDD is connected to the fifth sub-portion 15 and the power line VDD can easily supply the power signal to the fifth switch transistor T5, and, in addition, since the power line VDD is shared in the second direction Y, so the second sub-portion 12 is also required to be connected.

In conjunction with FIGS. 2 and 3, in another embodiment of the present application, exemplarily, the reference voltage line Vref extends along the first direction X and is connected to the fourth sub-portion 14. This configuration can make it easier for the reference voltage line Vref to supply the reference voltage signal to the fourth switch transistor T4 located within the fourth sub-portion 14.

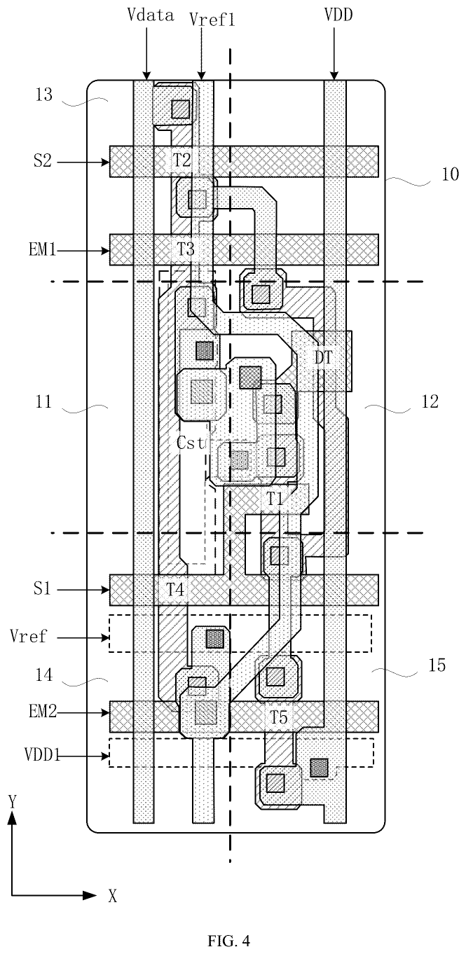

FIG. 4 is a diagram illustrating yet another sub-pixel structure according to an embodiment of the present application. Referring to FIG. 4, in another embodiment of the present application, exemplarily, the sub-pixel structure 10 further includes an auxiliary power line VDD1 extending along the first direction X. The auxiliary power line VDD1 and the power line VDD form a mesh power line. In the embodiment of the present application, this configuration can increase the area of the power line VDD and the impedance of the power line VDD can be reduced easily, and the uniformity of power signals supplied by the display panel can be improved.

In conjunction with FIGS. 2 and 4, exemplarily, the auxiliary power line VDD1 is connected to the fourth sub-portion 14 and the fifth sub-portion 15. Exemplarily, the auxiliary power line VDD1 is located below the second light emission control line EM2 and the pixel space can be further optimized easily.

With continued reference to FIG. 4, based on the preceding embodiment, exemplarily, the sub-pixel structure 10 further includes an auxiliary reference voltage line Vref1 extending along the second direction Y. The auxiliary reference voltage line Vref1 and the reference voltage line Vref form a mesh reference voltage line. Exemplarily, the auxiliary reference voltage line Vref1 is connected to the third sub-portion 13, the second sub-portion 12, the fifth sub-portion 15 and the fourth sub-portion 14 and not to increase the spatial size of the sub-pixel structure 10.

With continued reference to FIG. 2, based on the preceding embodiment, exemplarily, the power line VDD is referred to as a first power line, and the sub-pixel structure further includes a second power line VSS laid in an entire layer.

In the preceding embodiment, the sub-portion division of the transistors and the storage capacitor Cst is described. The configuration manner of films of the sub-pixel structure is described below but does not limit the present application.

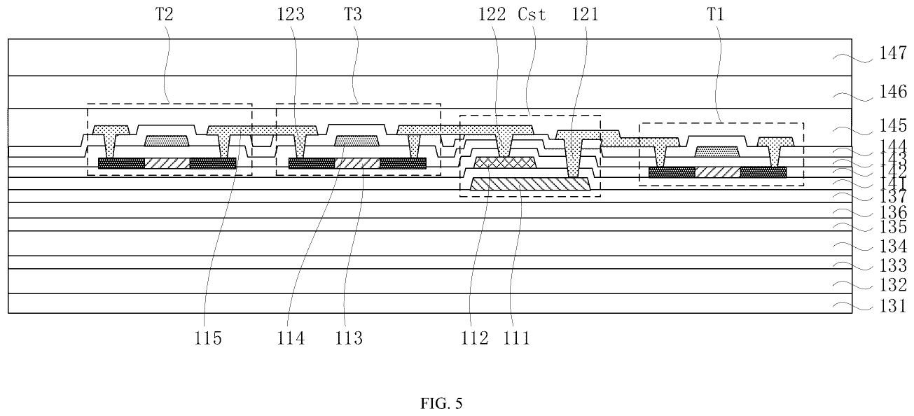

FIG. 5 is a diagram illustrating the structure of FIG. 3 taken along an A-A section. In conjunction with FIGS. 3 and 5, in an embodiment of the present application, exemplarily, the film structure of the sub-pixel structure 10 includes a first wire layer 111, a second wire layer 112, a semiconductor layer 113, a gate layer 114 and a third wire layer 115 that are stacked. Two plates of the storage capacitor Cst are disposed on the first wire layer 111 and the second wire layer 112 respectively. An active layer, a first end and a second end of the drive transistor DT (which is not shown in FIG. 5) as well as active layers, first ends and second ends of switch transistors (the second switch transistor T2, the third switch transistor T3 and the first switch transistor T1 are shown in FIG. 5) are disposed on the semiconductor layer 113. The first end and the second end of the drive transistor DT as well as first ends and second ends of switch transistors (the first switch transistor T1 to the fifth switch transistor T5 are included) are conductors formed by heavy doping of the semiconductor layer 113. The gate of the drive transistor DT as well as gates of the switch transistors (the first switch transistor T1 to the fifth switch transistor T5 are included) are disposed on the gate layer 114. Connection jump wires between different films are disposed on the third wire layer 115. Exemplarily, a connection jump wire between the second end of the drive transistor DT and the second switch transistor T2 is disposed on the third wire layer 115, a connection jump wire between the gate of the drive transistor DT and the first switch transistor T1 is disposed on the third wire layer 115, and a connection jump wire between the first switch transistor T1 and the fifth switch transistor T5 is disposed on the third wire layer 115.

With continued reference to FIG. 5, based on the preceding embodiments, exemplarily, the third wire layer 115 is electrically connected to the different films through vias. According to different depths of the vias, the vias may be divided into first-type vias, second-type vias, third-type vias and fourth-type vias.

Exemplarily, the third wire layer 115 is connected to the first wire layer 111 through a first-type via 121. For example, the third wire layer 115 is connected to a capacitance lower plate through the first-type via 121. The third wire layer 115 is connected to the second wire layer 112 through a second-type via 122. For example, the third wire layer 115 is connected to a capacitance upper plate through the second-type via 122.

The third wire layer 115 is connected to the semiconductor layer 113 through a third-type via 123. For example, the third wire layer 115 is connected to the first ends (or the second ends) of the transistors through third-type vias 123. The third wire layer 115 is connected to the gate layer 114 through a fourth-type via (which is not shown in FIG. 5). For example, the third wire layer 115 is connected to the gate of the drive transistor DT through the fourth-type via.

The first-type vias and the second-type vias have relatively deep etching depths and thereby are deep holes. The third-type vias and the fourth-type vias have relatively shallow etching depths and thereby are shallow holes.

Exemplarily, the deep holes and the shallow holes are prepared before the third wire layer is formed and are prepared using two processes respectively. For example, a mask is first adopted for punching the deep holes, and another mask is then adopted for punching the shallow holes. In the embodiment of the present application, this configuration can avoid occupying the pixel space due to relatively large openings of the shallow holes caused by the same process adopted for the deep holes and the shallow holes.

With continued reference to FIGS. 3 to 5, based on the preceding embodiments, exemplarily, the drive transistor DT and the switch transistors are n-type transistors, and the semiconductor material of the drive transistor DT and the switch transistors is metal oxide (such as indium gallium zinc oxide (IGZO)). Compared with other materials, using the IGZO as the semiconductor material enables the transistors to have the advantage of a small leakage current. The transistors may be single-gate transistors and the pixel space can be further reduced easily, and the pixel density of the display panel can be improved.

In other embodiments, the drive transistor DT and the switch transistors may be p-type transistors, and the semiconductor material of the drive transistor DT and the switch transistors may be low temperature polycrystalline silicon (P-si). To reduce the leakage current, the switch transistors may have horizontal double-gate structures. The horizontal double gate is equivalent to two transistors connected in series and the leakage current can be reduced.

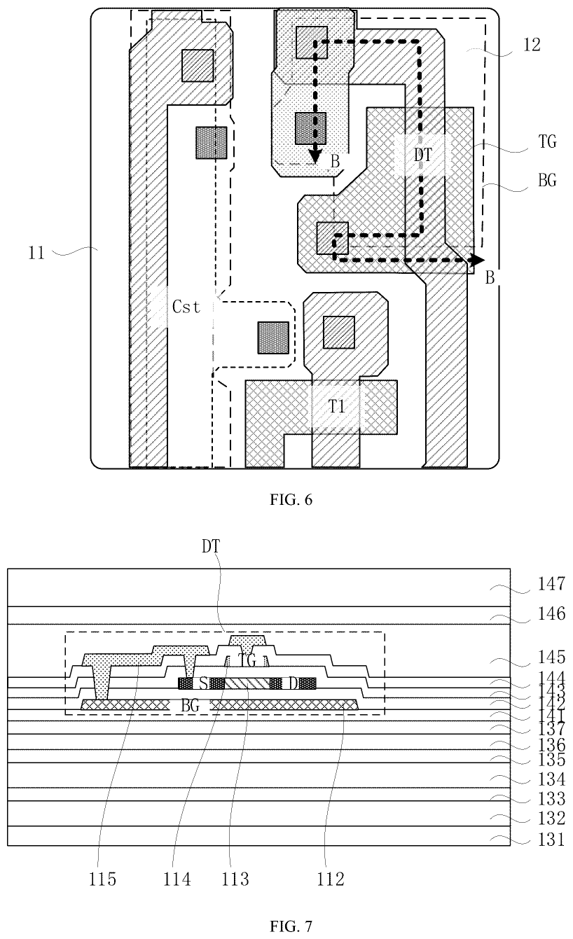

FIG. 6 is an enlarged diagram illustrating the structure of a first sub-portion and a second sub-portion according to an embodiment of the present application. FIG. 7 is a diagram illustrating the structure of FIG. 6 taken along a B-B section. FIG. 8 is an equivalent circuit diagram of a drive transistor of FIG. 6. Referring to FIGS. 6 to 8, in an embodiment of the present application, exemplarily, the drive transistor DT includes a top gate TG and a bottom gate BG. The bottom gate BG of the drive transistor DT is disposed on the second wire layer 112, and the top gate TG of the drive transistor DT is disposed on the gate layer 114. In the embodiment of the present application, the second wire layer 112 is used for disposing the bottom gate BG of the drive transistor DT and the drive transistor DT can form a perpendicular double-gate structure. One of the top gate TG or the bottom gate BG serves as a control gate while the other one of the top gate TG or the bottom gate BG serves as a gate for adjusting a threshold voltage and a more accurate control strategy can be supplied to the drive transistor DT easily.

With continued reference to FIGS. 6 to 8, exemplarily, the top gate TG of the drive transistor DT is the control gate, and the bottom gate BG of the drive transistor DT is connected to a source S of the drive transistor DT. This configuration can enable the top gate TG to receive the data signal and supply a corresponding drive current under the action of the data signal. The source S and a drain D of the drive transistor DT are disposed symmetrically. In a specific circuit, one end with a relatively low voltage serves as the source S while one end with a relatively high voltage serves as the drain D. In the embodiment of the present application, the first electrode of the drive transistor DT is connected to the second switch transistor T2, and the second switch transistor T2 has a relatively low voltage and thereby serves as the source S, so the bottom gate BG is connected to the source S (that is, the second switch transistor T2).

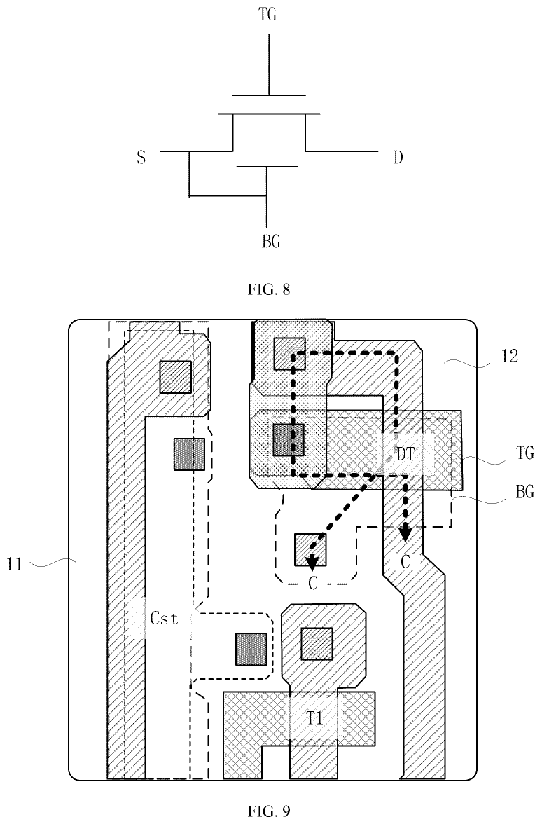

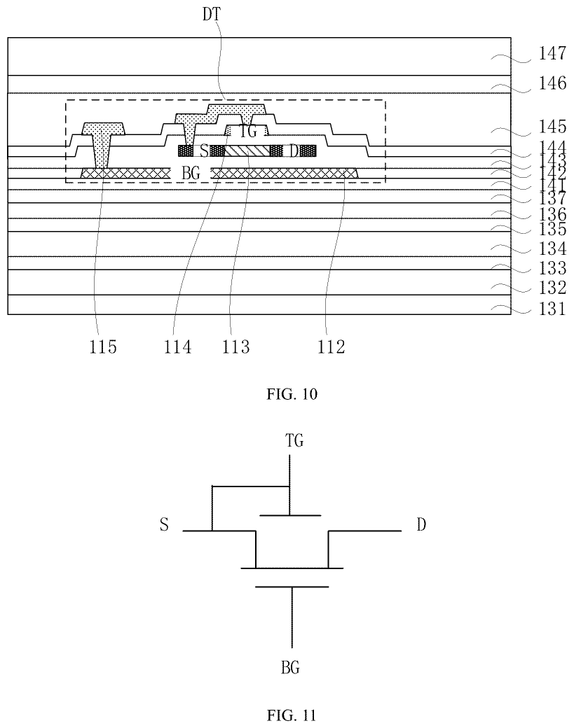

FIG. 9 is an enlarged diagram illustrating the structure of another first sub-portion and another second sub-portion according to an embodiment of the present application. FIG. 10 is a diagram illustrating the structure of FIG. 9 taken along a C-C section. FIG. 11 is an equivalent circuit diagram of a drive transistor of FIG. 9. Referring to FIGS. 9 to 11, in another embodiment of the present application, exemplarily, the bottom gate BG of the drive transistor DT is the control gate, and the top gate TG of the drive transistor DT is connected to the source S of the drive transistor DT. This configuration can enable the bottom gate BG to receive the data signal and supply a corresponding drive current under the action of the data signal. In the embodiment of the present application, the first electrode of the drive transistor DT is connected to the second switch transistor T2, and the second switch transistor T2 has the relatively low voltage and thereby serves as the source S, so the top gate TG is connected to the source S (that is, the second switch transistor T2).

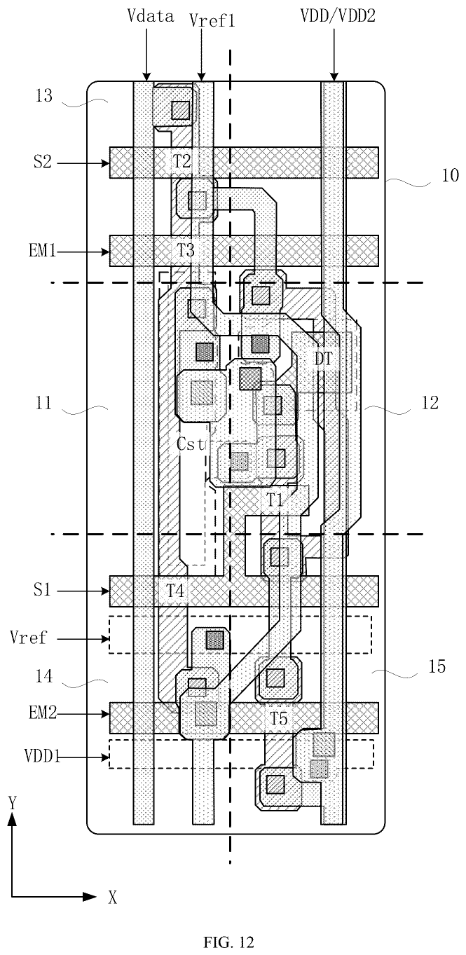

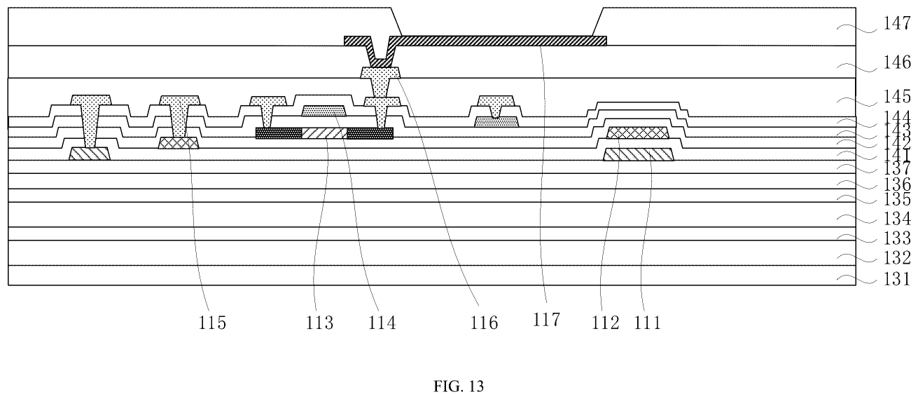

FIG. 12 is a diagram illustrating yet another sub-pixel structure according to an embodiment of the present application. FIG. 13 is a section diagram illustrating yet another sub-pixel structure according to an embodiment of the present application. Referring to FIGS. 12 and 13, based on the preceding embodiments, exemplarily, the sub-pixel structure 10 further includes a fourth wire layer 116. The fourth wire layer 116 is located on one side of the third wire layer 115 facing away from the first wire layer 111 and includes a second auxiliary power line VDD2 and an auxiliary reference voltage line Vref1. The power line VDD, the auxiliary power line VDD1 and the second auxiliary power line VDD2 form a composite mesh power line. Exemplarily, the second auxiliary power line VDD2 overlaps the power line VDD. The reference voltage line Vref and the auxiliary reference voltage line Vref1 form the mesh reference voltage line. In the embodiment of the present application, this configuration can further improve the uniformity of power signals and reference voltage signals in the display panel.

With continued reference to FIG. 13, based on the preceding embodiments, exemplarily, the sub-pixel structure 10 further includes an anode layer 117. The anode layer 117 is located on one side of the fourth wire layer 116 facing away from the first wire layer 111. The anode layer 117 includes an anode of the light-emitting device.

With continued reference to FIG. 13, based on the preceding embodiments, exemplarily, the bottom of the first wire layer 111 is also provided with films such as a buffer layer. Insulating layers are also disposed between wire layers. Exemplarily, the lowest layer is a base 131. For example, the base 131 may be an inorganic film such as glass. A first buffer layer 132 is located on the base 131. For example, the first buffer layer 132 may be made of an organic material such as polyimide. A second buffer layer 133 is located on one side of the first buffer layer 132 facing away from the base 131. For example, the second buffer layer 133 may be made of an inorganic material such as silicon oxide or silicon nitride. A third buffer layer 134 is located on one side of the second buffer layer 133 facing away from the base 131. For example, the third buffer layer 134 may be made of an organic material such as polyimide. A fourth buffer layer 135 is located on one side of the third buffer layer 134 facing away from the base 131. For example, the fourth buffer layer 135 may be made of an inorganic material such as silicon oxide or silicon nitride. A fifth buffer layer 136 is located on one side of the fourth buffer layer 135 facing away from the base 131. For example, the fifth buffer layer 136 may be made of an inorganic material such as aluminum nitride or gallium nitride. A sixth buffer layer 137 is located on one side of the fifth buffer layer 136 facing away from the base 131. For example, the sixth buffer layer 137 may be made of an inorganic material such as silicon oxide or silicon nitride. A first insulating layer 141 is located between the first wire layer 111 and the second wire layer 112. For example, the first insulating layer 141 may be made of an inorganic material such as silicon oxide or silicon nitride. A second insulating layer 142 is located between the second wire layer 112 and the semiconductor layer 113. For example, the second insulating layer 142 may be made of an inorganic material such as silicon oxide or silicon nitride. A third insulating layer 143 is located between the semiconductor layer 113 and the gate layer 114. For example, the third insulating layer 143 may be made of an inorganic material such as silicon oxide or silicon nitride. A fourth insulating layer 144 is located between the gate layer 114 and the third wire layer 115. For example, the fourth insulating layer 144 may be made of an inorganic material such as silicon oxide or silicon nitride. A fifth insulating layer 145 is located between the third wire layer 115 and the fourth wire layer 116. For example, the fifth insulating layer 145 may be made of an organic material such as photoresist. A sixth insulating layer 146 is located between the fourth wire layer 116 and the anode layer 117. For example, the sixth insulating layer 146 may be made of an organic material such as photoresist. A pixel defining layer 147 is located on one side of the anode layer 117 facing away from the base 131. For example, the pixel defining layer 147 may be made of an organic material such as photoresist.

Based on the preceding embodiments, the patterned structures of the films are further described in the embodiment of the present application but do not limit the present application.

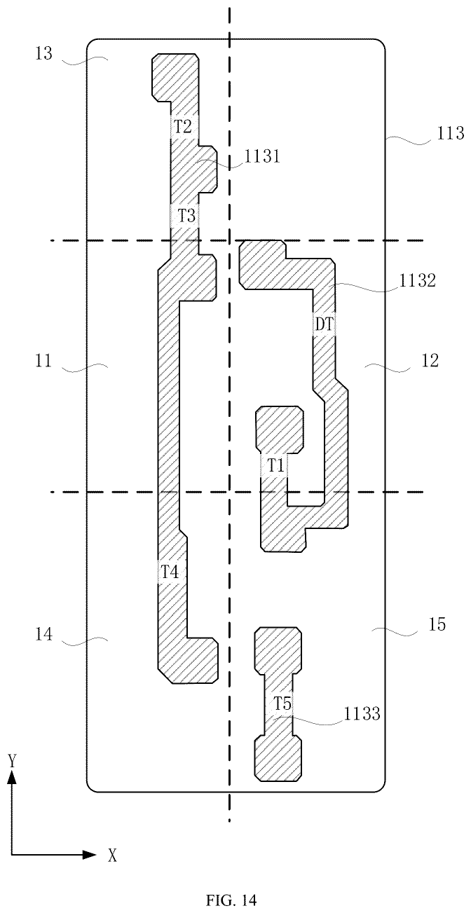

FIG. 14 is a diagram illustrating the patterned structure of a semiconductor layer according to an embodiment of the present application. Referring to FIGS. 12 and 14, in an embodiment of the present application, exemplarily, the semiconductor layer 113 includes a first semiconductor structure 1131, a second semiconductor structure 1132 and a third semiconductor structure 1133.

The first semiconductor structure 1131 extends along the second direction Y and is connected to the third sub-portion 13, the first sub-portion 11 and the fourth sub-portion 14. The first semiconductor structure 1131 is configured to form active layers of the second switch transistor T2, the third switch transistor T3 and the fourth switch transistor T4. Conductors are formed after the first semiconductor structure 1131 is heavily doped and sources and drains of the second switch transistor T2, the third switch transistor T3 and the fourth switch transistor T4 can be formed. Exemplarily, the first electrode (the source or the drain) of the second switch transistor T2 is connected to a data line through a via, the second electrode (the drain or the source) of the second switch transistor T2 is connected to the first electrode (the source or the drain) of the third switch transistor T3 through the heavily doped first semiconductor structure 1131 and is also electrically connected to the first electrode (the source or the drain) of the drive transistor DT through a connection jump wire, and the second electrode (the drain or the source) of the third switch transistor T3 is connected to the second electrode (the drain or the source) of the fourth switch transistor T4 through the heavily doped first semiconductor structure 1131. The first electrode (the source or the drain) of the fourth switch transistor T4 is connected to the reference voltage line Vref through a via.

The second semiconductor structure 1132 is located in the second sub-portion 12 and in the shape of an inverted G, and the long side direction of the second semiconductor structure 1132 is the second direction Y. The second semiconductor structure 1132 is configured to form active layers of the drive transistor DT and the first switch transistor T1. Conductors are formed after the second semiconductor structure 1132 is heavily doped and sources and drains of the drive transistor DT and the first switch transistor T1 can be formed. Exemplarily, the first electrode (the source or the drain) of the drive transistor DT is connected to the second electrode (the drain or the source) of the second switch transistor T2 through a connection jump wire, the second electrode (the drain or the source) of the drive transistor DT is connected to the second electrode (the drain or the source) of the first switch transistor T1 through the heavily doped second semiconductor structure 1132, and the first electrode (the source or the drain) of the first switch transistor T1 is connected to the gate of the drive transistor DT through a connection jump wire.

The third semiconductor structure 1133 is located in the fifth sub-portion 15 and extends along the second direction Y. The third semiconductor structure 1133 is configured to form an active layer of the fifth switch transistor T5. Conductors are formed after the third semiconductor structure 1133 is heavily doped and a source and a drain of the fifth switch transistor T5 can be formed. Exemplarily, the first electrode (the source or the drain) of the fifth switch transistor T5 is connected to the power line VDD through a via, and the second electrode (the drain or the source) of the fifth switch transistor T5 is connected to the second electrode of the drive transistor DT through a connection jump wire.

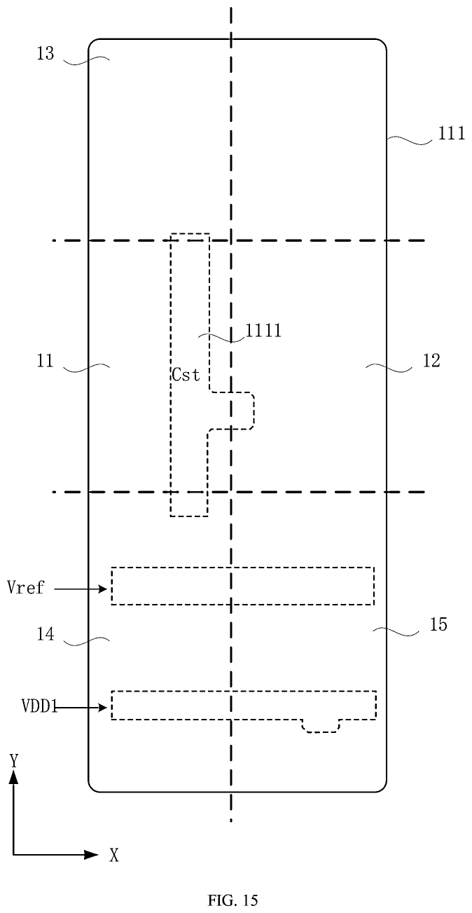

FIG. 15 is a diagram illustrating the patterned structure of a first wire layer according to an embodiment of the present application. Referring to FIGS. 12 and 15, in an embodiment of the present application, exemplarily, the first wire layer 111 includes a capacitor first plate 1111, the reference voltage line Vref and the auxiliary power line VDD1.

The capacitor first plate 1111 is located in the first sub-portion 11. The perpendicular projection of the capacitor first plate 1111 on the semiconductor layer 113 overlaps the first semiconductor structure 1131.

The reference voltage line Vref extends along the first direction X, is connected to the fourth sub-portion 14 and supplies a reference voltage to the at least one switch transistor located within the fourth sub-portion 14. Exemplarily, the at least one switch transistor located within the fourth sub-portion 14 is the fourth switch transistor T4, and the reference voltage line Vref is connected to the first electrode (the source or the drain) of the fourth switch transistor T4 through the via.

The auxiliary power line VDD1 extends along the first direction X, is connected to the fifth sub-portion 15 and supplies a power signal to the at least one switch transistor located within the fifth sub-portion 15. Exemplarily, the at least one switch transistor located within the fifth sub-portion 15 is the fifth switch transistor T5, and the auxiliary power line VDD1 forms the mesh power line with the power line VDD located on the third wire layer 115. The fifth switch transistor T5 is connected to the power line VDD through a via. The auxiliary power line VDD1 is also connected to the power line VDD through a via.

In other embodiments, the reference voltage line Vref and/or the auxiliary power line VDD1 may also be located on the second wire layer 112.

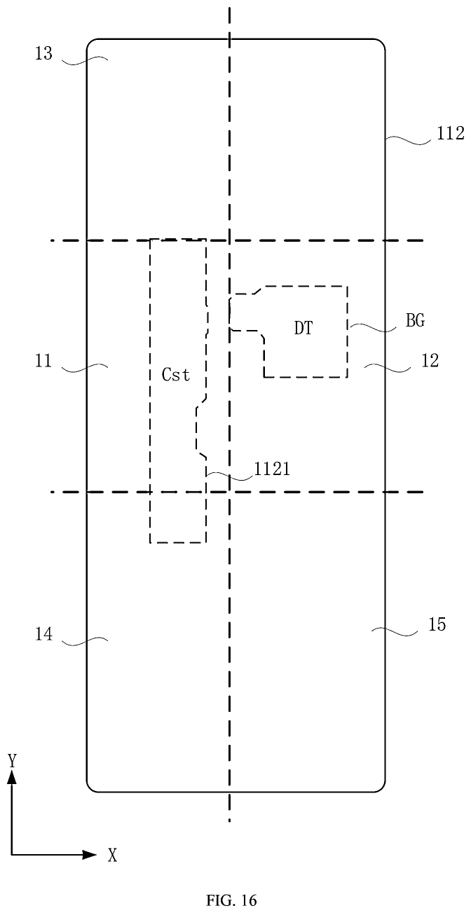

FIG. 16 is a diagram illustrating the patterned structure of a second wire layer according to an embodiment of the present application. Referring to FIGS. 12 and 16, in an embodiment of the present application, exemplarily, the second wire layer 112 includes a capacitor second plate 1121 and the bottom gate BG.

The capacitor second plate 1121 is located in the first sub-portion 11. The perpendicular projection of the capacitor second plate 1121 on the first wire layer 111 overlaps the capacitor first plate 1111. The overlapping position forms the storage capacitor Cst.

The bottom gate BG is located in the second sub-portion 12. The perpendicular projection of the bottom gate BG on the semiconductor layer 113 overlaps the second semiconductor structure 1132. The overlapping position is defined as the drive transistor DT.

In the embodiment of the present application, the second wire layer 112 is used for disposing the bottom gate BG of the drive transistor DT without adding a new film and occupying the pixel space and the display panel can be ensured to be lighter and thinner and compact.

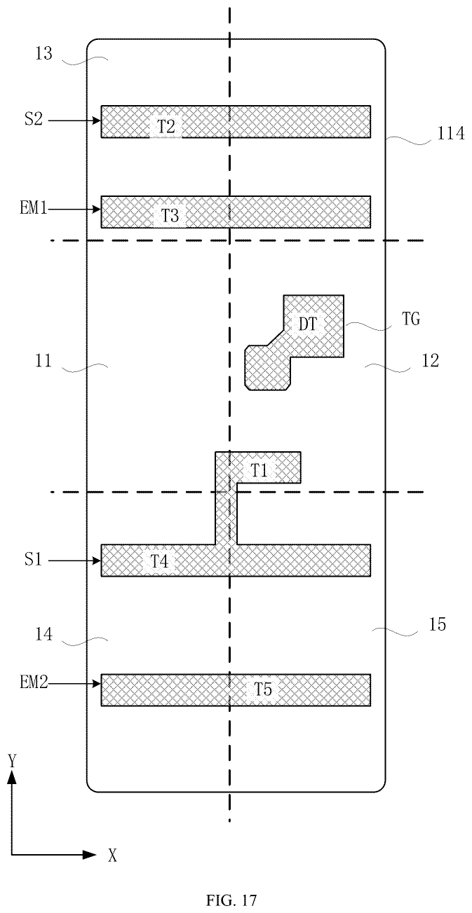

FIG. 17 is a diagram illustrating the patterned structure of a gate layer according to an embodiment of the present application. Referring to FIGS. 12 and 17, in an embodiment of the present application, exemplarily, the gate layer 114 includes the second scan line S2, the first light emission control line EM1, the top gate TG, the first scan line S1 and the second light emission control line EM2.

The second scan line S2 extends along the first direction X and is connected to the third sub-portion 13. The perpendicular projection of the second scan line S2 on the semiconductor layer 113 overlaps the first semiconductor structure 1131. The overlapping position is defined as one switch transistor located in the third sub-portion 13, that is, the second switch transistor T2.

The first light emission control line EM1 extends along the first direction X and is connected to the third sub-portion 13. The perpendicular projection of the first light emission control line EM1 on the semiconductor layer 113 overlaps the first semiconductor structure 1131. The overlapping position is defined as one switch transistor located in the third sub-portion 13, that is, the third switch transistor T3.

The top gate TG is located in the second sub-portion 12. The perpendicular projection of the top gate TG on the semiconductor layer 113 overlaps the second semiconductor structure 1132. The overlapping position is defined as the drive transistor DT.

The first scan line S1 extends along the first direction X, is in the shape of a left inverted “h” and is connected to the fourth sub-portion 14 and the second sub-portion 12. The perpendicular projection of the first scan line S1 on the semiconductor layer 113 overlaps the first semiconductor structure 1131, and the overlapping position is defined as one switch transistor located in the fourth sub-portion 14, that is, the fourth switch transistor T4. The perpendicular projection of the first scan line S1 on the semiconductor layer 113 further overlaps the second semiconductor structure 1132, and the overlapping position is defined as one switch transistor located in the second sub-portion 12, that is, the first switch transistor T1.

The second light emission control line EM2 extends along the first direction X and is connected to the fifth sub-portion 15. The perpendicular projection of the second light emission control line EM2 on the semiconductor layer 113 overlaps the third semiconductor structure 1133. The overlapping position is defined as one switch transistor located in the fifth sub-portion 15, that is, the fifth switch transistor T5.

In the embodiment of the present application, the transistors are top-gate transistors and a metal layer can be formed on the semiconductor layer 111 as gates of the transistors. For an IGZO-type semiconductor material, oxygen can be differentiated in the semiconductor layer 111 after the gate layer 114 is formed and oxygen can be differentiated in a channel region and a source and drain region on the semiconductor layer 111, to form the transistors. For an LTPS-type semiconductor material, ions can be implanted into the semiconductor layer 111 after the gate layer 114 is formed and the transistors can be formed.

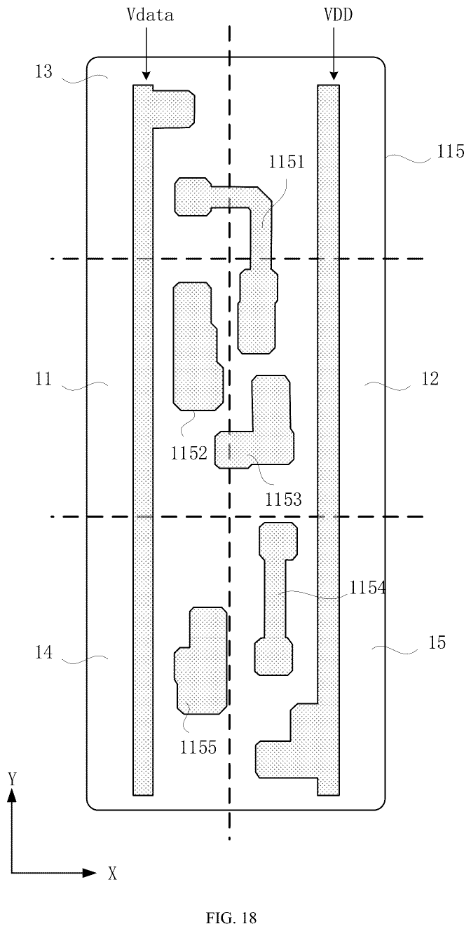

FIG. 18 is a diagram illustrating the patterned structure of a third wire layer according to an embodiment of the present application. Referring to FIGS. 12 and 18, in an embodiment of the present application, exemplarily, the third wire layer 115 includes the data line Vdata, the power line VDD, a first jump wire 1151, a second jump wire 1152, a third jump wire 1153, a fourth jump wire 1154 and a fifth jump wire 1155.

The data line Vdata extends along the second direction Y, is connected to the third sub-portion 13 and supplies the data signal to the switch transistor (that is, the second switch transistor T2) located in the third sub-portion 13. The perpendicular projection of the data line Vdata on the semiconductor layer 113 is located on the outer side of the first semiconductor structure 1131. This configuration can facilitate a reduction in the overlapping area between signal lines and interferences between the signal lines can be reduced.

The power line VDD extends along the second direction Y, is connected to the fifth sub-portion 15 and supplies the power signal to the switch transistor (that is, the fifth switch transistor T5) located in the fifth sub-portion 15. The perpendicular projection of the power line VDD on the semiconductor layer 113 is located on the outer side of the third semiconductor structure 1133. This configuration can facilitate the reduction in the overlapping area between the signal lines and the interferences between the signal lines can be reduced.

Two ends of the first jump wire 1151 are located in the second sub-portion 12 and the third sub-portion 13 respectively. The first jump wire 1151 is configured to connect the drive transistor DT located within the second sub-portion 12 and the switch transistor (that is, the second switch transistor T2) located within the third sub-portion 13. Exemplarily, one end of the first jump wire 1151 is connected to the first electrode of the drive transistor DT through a via while the other end of the first jump wire 1151 is connected to the second electrode of the second switch transistor T2 through a via.

The second jump wire 1152 is located in the first sub-portion 11 and configured to connect the switch transistor (that is, the third switch transistor T3) located within the third sub-portion 13 and the capacitor second plate 1121 located within the first sub-portion 11. Exemplarily, one end of the second jump wire 1152 is connected to the second electrode of the third switch transistor T3 through a via while the other end of the second jump wire 1152 is connected to the capacitor second plate 1121 through a via. In other embodiments, two ends of the second jump wire 1152 may also be located in the first sub-portion 11 and the third sub-portion 13 respectively.

The third jump wire 1153 is located in the second sub-portion 12 and configured to connect the drive transistor DT, the switch transistor (that is, the first switch transistor T1) and the capacitor first plate 1111 that are located within the second sub-portion 12. Exemplarily, part of the third jump wire 1153 is connected to the gate of the drive transistor DT through a via, another part of the third jump wire 1153 is connected to the first electrode of the first switch transistor T1 through a via, and yet another part of the third jump wire 1153 is connected to the capacitor first plate 1111 through a via.

The fourth jump wire 1154 is located in the fifth sub-portion 15 and configured to connect the switch transistor (that is, the first switch transistor T1) located within the second sub-portion 12 and the switch transistor (that is, the fifth switch transistor) located within the fifth sub-portion 15. Exemplarily, one end of the fourth jump wire 1154 is connected to the second electrode of the first switch transistor T1 through a via while the other end of the fourth jump wire 1154 is connected to the second electrode of the fifth switch transistor T5 through a via. In other embodiments, two ends of the fourth jump wire 1154 may also be located in the second sub-portion 12 and the fifth sub-portion 15 respectively.

The fifth jump wire 1155 is located in the fourth sub-portion 14 and configured to connect the switch transistor (that is, the fourth switch transistor T4) and the reference voltage line Vref that are located within the fourth sub-portion 14. Exemplarily, part of the fifth jump wire 1155 is connected to the first electrode of the fourth switch transistor T4 through a via while another part of the fifth jump wire 1155 is connected to the reference voltage line Vref through a via.

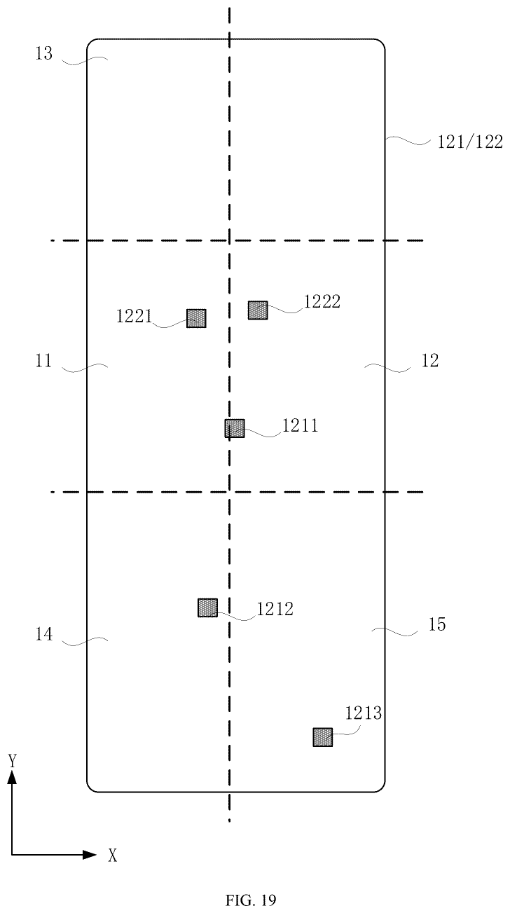

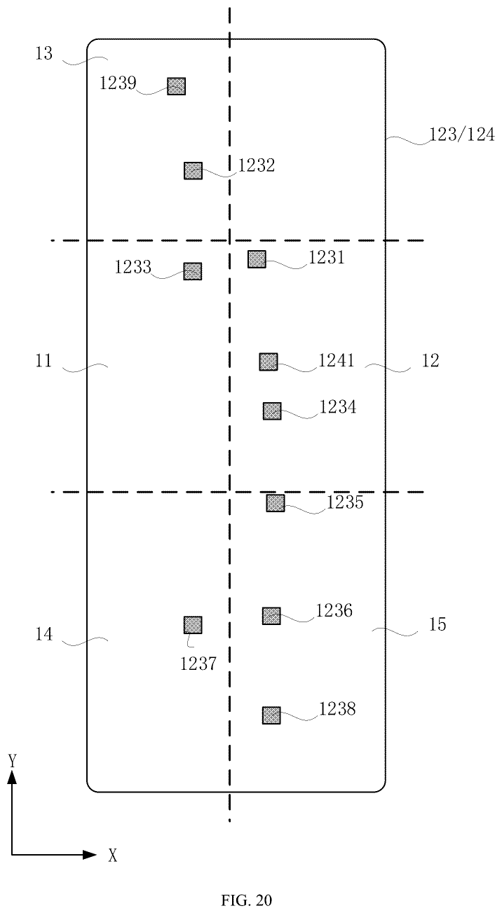

FIG. 19 is a diagram illustrating the patterned structure of first-type vias and second-type vias according to an embodiment of the present application. FIG. 20 is a diagram illustrating the patterned structure of third-type vias and fourth-type vias according to an embodiment of the present application. Referring to FIGS. 12 and 18 to 20, in an embodiment of the present application, exemplarily, part of the first jump wire 1151 is connected to the first electrode of the drive transistor DT through a third-type via 1231 while another part of the first jump wire 1151 is connected to the second electrode of the switch transistor (that is, the second switch transistor T2) located within the third sub-portion 13 through a third-type via 1232. Exemplarily, yet another part of the first jump wire 1151 is connected to the bottom gate BG located within the second sub-portion 12 through a second-type via 1222.

The second jump wire 1152 is connected to the second electrode of the switch transistor (that is, the third switch transistor T3) within the third sub-portion 13 through a third-type via 1233 and to the capacitor second plate 1121 through a second-type via 1221.

The third jump wire 1153 is connected to the gate of the drive transistor DT through a fourth-type via 1241, to the first electrode of the switch transistor (that is, the first switch transistor T1) within the second sub-portion 12 through a third-type via 1234 and to the capacitor first plate 1111 through a first-type via 1211.

The end of the fourth jump wire 1154 is connected to the second electrode of the switch transistor (that is, the first switch transistor T1) located within the second sub-portion 12 through a third-type via 1235 while the other end of the fourth jump wire 1154 is connected to the second electrode of the switch transistor (that is, the fifth switch transistor T5) located within the fifth sub-portion 15 through a third-type via 1236.

The fifth jump wire 1155 is connected to the first electrode of the switch transistor (that is, the fourth switch transistor T4) located within the fourth sub-portion 14 through a third-type via 1237 and to the reference voltage line Vref through a first-type via 1212.

The power line VDD is connected to the auxiliary power line VDD1 located on the first wire layer 111 through a first-type via 1213 and to the first electrode of the switch transistor (that is, the fifth switch transistor T5) located within the fifth sub-portion 15 through a third-type via 1238.

The data line Vdata is connected to the first electrode of the switch transistor (that is, the second switch transistor T2) located within the third sub-portion 13 through a third-type via 1239.

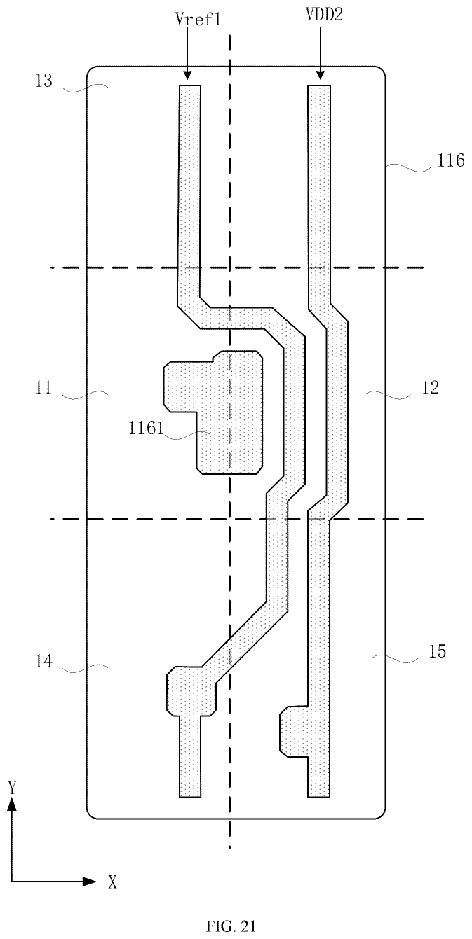

FIG. 21 is a diagram illustrating the patterned structure of a fourth wire layer according to an embodiment of the present application. Referring to FIGS. 12 and 21, in an embodiment of the present application, exemplarily, the fourth wire layer 116 includes the second auxiliary power line VDD2, the auxiliary reference voltage line Vref1 and an anode jump wire 1161.

The second auxiliary power line VDD2 extends along the second direction Y. The perpendicular projection of the second auxiliary power line VDD2 on the semiconductor layer 113 is located on the outer side of the third semiconductor structure 1133. Exemplarily, the second auxiliary power line VDD2 overlaps the power line VDD.

The auxiliary reference voltage line Vref1 extends along the second direction Y and avoids the first sub-portion 11. This configuration can make it easier to avoid the effect of the reference voltage line Vref1 on the storage capacitor Cst.

The anode jump wire 1161 is located in the first sub-portion 11 and/or the second sub-portion 12 and configured to connect the capacitor second plate 1121 and the anode.

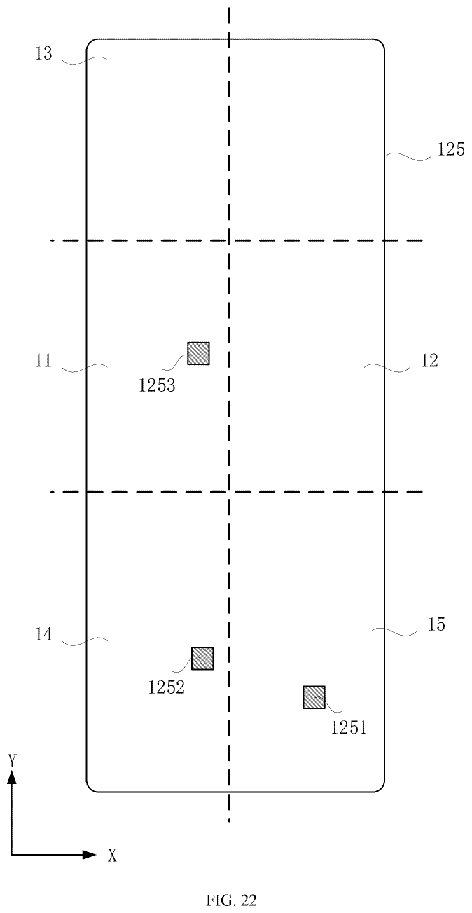

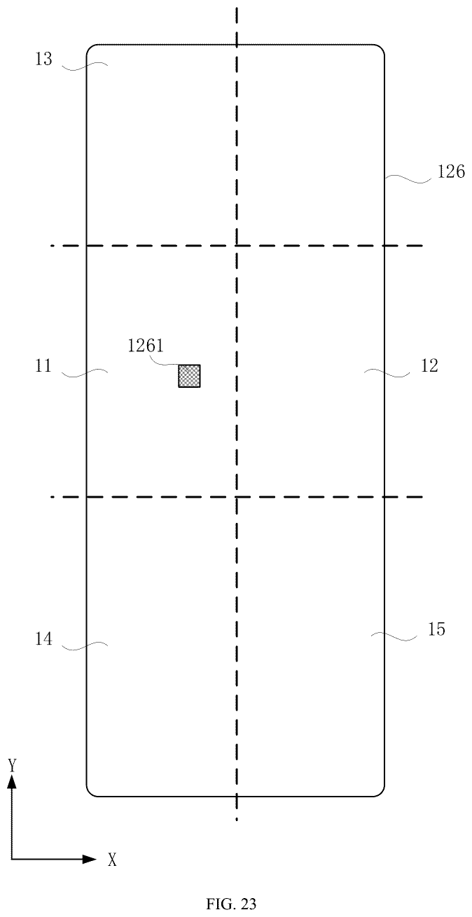

FIG. 22 is a diagram illustrating the patterned structure of fifth-type vias according to an embodiment of the present application. FIG. 23 is a diagram illustrating the patterned structure of sixth-type vias according to an embodiment of the present application. Referring to FIGS. 12 and 21 to 23, in an embodiment of the present application, exemplarily, the second auxiliary power line VDD2 is connected to the power line VDD located on the third wire layer 115 through a fifth-type via 1251.

The auxiliary reference voltage line Vref1 is connected to the fifth jump wire 1155 located on the third wire layer 115 through a fifth-type via 1252.

The anode jump wire 1161 is connected to the second jump wire 1152 located on the third wire layer 115 through a fifth-type via 1253.

The anode is connected to the anode jump wire 1161 through a sixth-type via 1261.

It is to be noted that the film structure of the sub-pixel structure 10 including the first wire layer 111, the second wire layer 112, the semiconductor layer 113, the gate layer 114 and the third wire layer 115 is exemplarily illustrated in the preceding embodiments. This does not limit the present application. In other embodiments, the number of films of the sub-pixel structure 10 may also be further reduced.

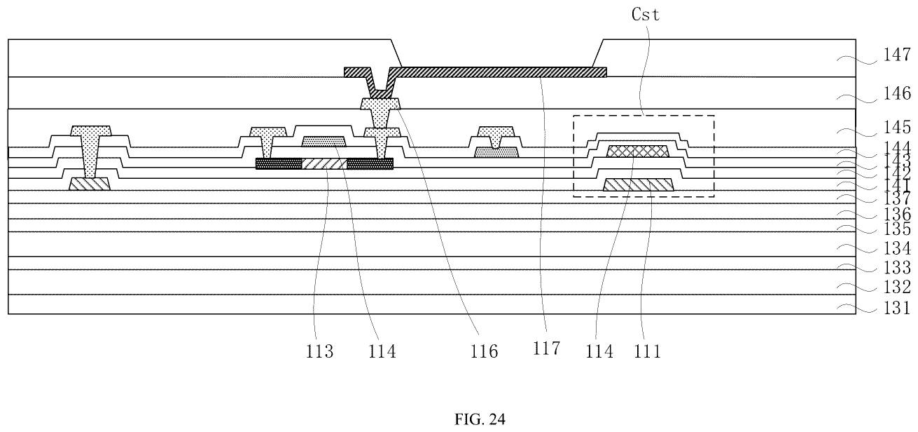

FIG. 24 is a section diagram illustrating the structure of yet another sub-pixel structure according to an embodiment of the present application. Referring to FIG. 24, in an embodiment of the present application, exemplarily, the film structure of the sub-pixel structure 10 includes the first wire layer 111, the semiconductor layer 113, the gate layer 114 and the third wire layer 115. Unlike the preceding embodiments, the two plates of the storage capacitor Cst are disposed on the first wire layer 111 and the gate layer 114 respectively. That is, the gate layer 114 also serves as the second wire layer 112 in the preceding embodiments. In the embodiment of the present application, this configuration can facilitate a reduction in the number of films and the display panel can become lighter and thinner easily.

Exemplarily, at least part of connection lines between the drive transistor DT and the switch transistors as well as at least part of connection lines between the switch transistors are disposed on the third wire layer 113.

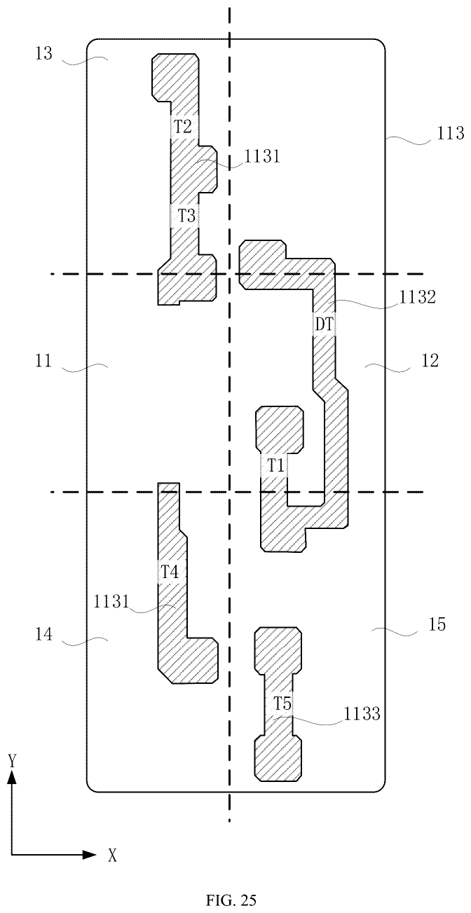

FIG. 25 is a diagram illustrating the patterned structure of another semiconductor layer according to an embodiment of the present application. Referring to FIG. 25, unlike the preceding embodiments, the first semiconductor structure 1131 avoids the first sub-portion 11. This configuration can prevent the first semiconductor structure 1131 from being located between the capacitor first plate and the capacitor second plate. Exemplarily, the second electrode of the third switch transistor T3 may be connected to the second electrode of the fourth switch transistor T4 in the manner of a connection jump wire.

It is to be noted that the case where the first direction X is perpendicular to the second direction Y is exemplarily illustrated in the preceding embodiments, and the first direction X may also not be perpendicular to the second direction Y according to requirements in other embodiments.

An embodiment of the present application further provides a display panel. The display panel includes multiple sub-pixel structures 10 according to any embodiment of the present application and has similar principles and achieved effects. Details are not repeated.

An embodiment of the present application further includes a display device. For example, the display device may be a mobile phone, a computer, a tablet computer, or a wearable device. The display device includes the display panel according to any embodiment of the present application and has similar principles and achieved effects. Details are not repeated.

An embodiment of the present application further provides a preparation method for a display panel. The preparation method for a display panel is applicable to the display panel according to any embodiment of the present application and can have corresponding beneficial effects. Exemplarily, the preparation method for a display panel includes the steps below.

A base is divided into multiple sub-pixel regions, and the multiple sub-pixel regions are divided into a first sub-portion, a second sub-portion, a third sub-portion, a fourth sub-portion and a fifth sub-portion, where the first sub-portion and the second sub-portion are arranged along a first direction; the third sub-portion, the first sub-portion and the fourth sub-portion are arranged along a second direction sequentially; the second direction intersects the first direction; the fifth sub-portion and the fourth sub-portion are parallel in the first direction; and the second sub-portion and the fifth sub-portion are parallel in the second direction.

A storage capacitor is formed within the first sub-portion, a drive transistor and at least one switch transistor connected to a control terminal of the drive transistor are formed within the second sub-portion, at least one switch transistor connected to a first electrode of the drive transistor is formed within the third sub-portion, at least one switch transistor connected to the storage capacitor is formed within the fourth sub-portion, and at least one switch transistor connected to a second electrode of the drive transistor is formed within the fifth sub-portion.

Exemplarily, a preparation method for the storage capacitor Cst includes the steps below.

Referring to FIGS. 13 and 15, a first wire layer 111 is formed and patterned to form a capacitor first plate 1111, where the capacitor first plate 1111 is located in the first sub-portion 11.

Exemplarily, the material of the first wire layer 111 includes one or a combination of molybdenum, gold, silver, copper, lithium, sodium, potassium, magnesium, aluminum, or zinc. The first wire layer 111 may be formed using a process such as vaporation or magnetron sputtering and then patterned using photolithography and etching processes.

Referring to FIG. 13, a first insulating layer 141 is formed on the first wire layer 111.

Exemplarily, the material of the first insulating layer 141 may be, for example, an inorganic material such as silicon oxide or silicon nitride and may be formed using a physical vapor deposition process or a chemical vapor deposition process.

Referring to FIGS. 13 and 16, a second wire layer 112 is formed on the first insulating layer and patterned to form a capacitor second plate 1121, where the capacitor second plate 1121 overlaps the capacitor first plate to form the storage capacitor Cst.

Exemplarily, the material of the second wire layer 112 includes one or a combination of molybdenum, gold, silver, copper, lithium, sodium, potassium, magnesium, aluminum, or zinc. The second wire layer 112 may be formed using a process such as vaporation or magnetron sputtering and then patterned using photolithography and etching processes.

Based on the preceding embodiment, exemplarily, a preparation method for transistors includes the steps below.

Referring to FIG. 13, a second insulating layer 142 is formed on the second wire layer 112.

Exemplarily, the material of the second insulating layer 142 may be, for example, an inorganic material such as silicon oxide or silicon nitride and may be formed using a physical vapor deposition process or a chemical vapor deposition process.

Referring to FIGS. 13 and 14, a semiconductor layer 113 is formed on the second insulating layer and patterned to form semiconductor structures (a first semiconductor structure 1131, a second semiconductor structure 1132 and a third semiconductor structure 1133 are included).

Referring to FIG. 13, a third insulating layer 143 is formed on the semiconductor layer 113.

Exemplarily, the material of the third insulating layer 143 may be, for example, an inorganic material such as silicon oxide or silicon nitride and may be formed using a physical vapor deposition process or a chemical vapor deposition process.

Referring to FIGS. 13 and 17, a gate layer 114 is formed on the third insulating layer and patterned to form gates of the drive transistor DT and switch transistors, where positions at which the drive transistor DT intersects the semiconductor structures form the drive transistor DT, and positions at which the gates of the switch transistors intersect the semiconductor structures form the switch transistors.

Exemplarily, the material of the gate layer 114 includes one or a combination of molybdenum, gold, silver, copper, lithium, sodium, potassium, magnesium, aluminum, or zinc. The gate layer 114 may be formed using a process such as vaporation or magnetron sputtering and then patterned using photolithography and etching processes.

Referring to FIG. 13, a fourth insulating layer 144 is formed on the gate layer 114.

Exemplarily, the material of the fourth insulating layer 144 may be, for example, an inorganic material such as silicon oxide or silicon nitride and may be formed using a physical vapor deposition process or a chemical vapor deposition process.

Referring to FIGS. 13 and 19, a first-type via 121 is formed at a depth corresponding to a position of the first wire layer 111 and a second-type via 122 is formed at a depth corresponding to a position of the second wire layer 112.

Exemplarily, the first-type vias 121 and the second-type vias 122 are formed using a deep hole etching process.

Referring to FIGS. 13 and 20, a third-type via 123 is formed at a depth corresponding to a position of the semiconductor layer 113 and a fourth-type via 124 is formed at a depth corresponding to a position of the gate layer 114.

Exemplarily, the third-type vias 123 and the fourth-type vias 124 are formed using a shallow hole etching process.

Referring to FIGS. 13 and 18, a third wire layer 115 is formed on the fourth insulating layer 144 and patterned to form jump wires (a first jump wire 1151, a second jump wire 1152, a third jump wire 1153, a fourth jump wire 1154 and a fifth jump wire 1155 are included), a data line Vdata and a power line VDD.

Exemplarily, the material of the third wire layer 115 includes one or a combination of molybdenum, gold, silver, copper, lithium, sodium, potassium, magnesium, aluminum, or zinc. The third wire layer 115 may be formed using a process such as vaporation or magnetron sputtering and then patterned using photolithography and etching processes. The third wire layer 115 can be electrically connected to other wire layers by injecting vias.

Exemplarily, after the third wire layer 115 is formed, the preparation method further includes the steps below.

Referring to FIG. 13, a fifth insulating layer 145 is formed on the third wire layer 115.

Exemplarily, the material of the fifth insulating layer 145 may be, for example, an organic material such as photoresist and may be formed using a spin coating process.

Referring to FIGS. 13 and 22, a fifth-type via 125 is formed at the depth corresponding to the position of the third wire layer 115.

Exemplarily, the fifth-type vias 125 are formed using a shallow hole etching process.

Referring to FIGS. 13 and 21, a fourth wire layer 116 is formed on the fifth insulating layer 145 and patterned to form a second auxiliary power line VDD2, an auxiliary reference voltage line Vref1 and an anode jump wire 1161.

Exemplarily, the material of the fourth wire layer 116 includes one or a combination of molybdenum, gold, silver, copper, lithium, sodium, potassium, magnesium, aluminum, or zinc. The fourth wire layer 116 may be formed using a process such as vaporation or magnetron sputtering and then patterned using photolithography and etching processes. The fourth wire layer 116 can be electrically connected to the third wire layer 115 by injecting vias.

Referring to FIG. 13, a sixth insulating layer 146 is formed on the fourth wire layer 116.

Exemplarily, the material of the sixth insulating layer 146 may be, for example, an organic material such as photoresist and may be formed using a spin coating process.

Referring to FIGS. 13 and 23, sixth-type vias 126 are formed corresponding to the depth at the position of the fourth wire layer 116.

Exemplarily, the sixth-type vias 126 are formed using a shallow hole etching process.

Referring to FIG. 13, an anode layer 117 is formed on the sixth insulating layer 146 and patterned to form an anode.

Exemplarily, the material of the anode layer includes indium tin oxide (ITO), silver, or a combination of ITOsilverITO (ITO/Ag/ITO).

After the anode layer 117 is formed, processes such as forming a light-emitting layer and packaging are also included. Details are not repeated in the present application.

It is to be understood that various forms of processes shown above may be adopted with steps reordered, added or deleted. For example, the steps described in the present application may be performed in parallel, sequentially or in different sequences, as long as the desired results of the embodiments of the present application can be achieved, and no limitation is imposed herein.

What is claimed is:

1. A sub-pixel structure, comprising a first sub-portion, a second sub-portion, a third sub-portion, a fourth sub-portion and a fifth sub-portion,
wherein the first sub-portion and the second sub-portion are arranged along a first direction, and the third sub-portion, the first sub-portion and the fourth sub-portion are arranged along a second direction sequentially, wherein the second direction intersects the first direction;
wherein the fifth sub-portion and the fourth sub-portion are parallel in the first direction, and the second sub-portion and the fifth sub-portion are parallel in the second direction; and
wherein a storage capacitor is disposed within the first sub-portion, a drive transistor and at least one switch transistor connected to a control terminal of the drive transistor are disposed within the second sub-portion, at least one switch transistor connected to a first electrode of the drive transistor is disposed within the third sub-portion, at least one switch transistor connected to the storage capacitor is disposed within the fourth sub-portion, and at least one switch transistor connected to a second electrode of the drive transistor is disposed within the fifth sub-portion.

2. The sub-pixel structure of claim 1, wherein the drive transistor and a first switch transistor are disposed within the second sub-portion, wherein a gate of the first switch transistor is electrically connected to a first scan line, a first electrode of the first switch transistor is electrically connected to a gate of the drive transistor, and a second electrode of the first switch transistor is electrically connected to the second electrode of the drive transistor;
a second switch transistor and a third switch transistor are disposed within the third sub-portion, wherein a gate of the second switch transistor is electrically connected to a second scan line, a first electrode of the second switch transistor is electrically connected to a data line, and a second electrode of the second switch transistor is electrically connected to the first electrode of the drive transistor; a gate of the third switch transistor is electrically connected to a first light emission control line, a first electrode of the third switch transistor is electrically connected to the first electrode of the drive transistor, and a second electrode of the third switch transistor is electrically connected to the storage capacitor;
a fourth switch transistor is disposed within the fourth sub-portion, wherein a gate of the fourth switch transistor is electrically connected to the first scan line, a first electrode of the fourth switch transistor is electrically connected to a reference voltage line, and a second electrode of the fourth switch transistor is electrically connected to the second electrode of the third switch transistor; and
a fifth switch transistor is disposed within the fifth sub-portion, wherein a gate of the fifth switch transistor is electrically connected to a second light emission control line, a first electrode of the fifth switch transistor is electrically connected to a power line, and a second electrode of the fifth switch transistor is electrically connected to the second electrode of the drive transistor,
wherein the drive transistor, the first switch transistor, the second switch transistor, the third switch transistor, the fourth switch transistor and the fifth switch transistor are oxide transistors.

3. The sub-pixel structure of claim 2, wherein the second scan line, the first light emission control line, the first scan line and the second light emission control line extend along the first direction,
wherein the second scan line and the first light emission control line are connected to the third sub-portion, the first scan line is connected to the fourth sub-portion, and the second light emission control line is connected to the fifth sub-portion; and
wherein the second scan line, the first light emission control line, the first scan line and the second light emission control line are arranged sequentially in the second direction.

4. The sub-pixel structure of claim 2, wherein the data line and the power line extend along the second direction, the data line is connected to the third sub-portion, the first sub-portion and the fourth sub-portion, and the power line is connected to the second sub-portion and the fifth sub-portion; and
the sub-pixel structure further comprises an auxiliary power line extending along the first direction, wherein the auxiliary power line and the power line form a mesh power line,
wherein the auxiliary power line is connected to the fourth sub-portion and the fifth sub-portion.

5. The sub-pixel structure of claim 2, wherein the reference voltage line extends along the first direction and is connected to the fourth sub-portion; and
the sub-pixel structure further comprises an auxiliary reference voltage line extending along the second direction, wherein the auxiliary reference voltage line and the reference voltage line form a mesh reference voltage line.

6. The sub-pixel structure of claim 1, wherein a film structure of the sub-pixel structure comprises a first wire layer, a second wire layer, a semiconductor layer, a gate layer and a third wire layer, and the first wire layer, the second wire layer, the semiconductor layer, the gate layer and the third wire layer are stacked;
two plates of the storage capacitor are disposed on the first wire layer and the second wire layer respectively;
an active layer of the drive transistor, a first end of the drive transistor, a second end of the drive transistor, an active layer of the at least one switch transistor, a first end of the at least one switch transistor and a second end of the at least one switch transistor are disposed on the semiconductor layer, wherein the first end of the drive transistor, the second end of the drive transistor, the first end the at least one switch transistor and the second end of the at least one switch transistor are conductors formed by heavy doping of the semiconductor layer;
a gate of the drive transistor and a gate of the at least one switch transistor are disposed on the gate layer; and
connection jump wires between different films are disposed on the third wire layer.

7. The sub-pixel structure of claim 6, wherein the third wire layer is connected to the first wire layer through a first-type via, and the third wire layer is connected to the second wire layer through a second-type via; and
the third wire layer is connected to the semiconductor layer through a third-type via and the third wire layer is connected to the gate layer through a fourth-type via,
wherein each of a depth of the first-type via and a depth of the second-type via is greater than a depth of the third-type via and, each of a depth of the first-type via and a depth of the second-type via is greater than a depth of the fourth-type via.

8. The sub-pixel structure of claim 6, wherein the drive transistor comprises a top gate and a bottom gate, wherein the bottom gate of the drive transistor is disposed on the second wire layer, and the top gate of the drive transistor is disposed on the gate layer,
wherein the top gate of the drive transistor is a control gate, and the bottom gate of the drive transistor is connected to a source of the drive transistor; or the bottom gate of the drive transistor is a control gate, and the top gate of the drive transistor is connected to a source of the drive transistor; and
wherein the second electrode of the drive transistor is the source.

9. The sub-pixel structure of claim 6, wherein the semiconductor layer comprises:
a first semiconductor structure extending along the second direction and connected to the third sub-portion, the first sub-portion and the fourth sub-portion;
a second semiconductor structure located in the second sub-portion and being in a shape of an inverted G, wherein a long side direction of the second semiconductor structure is the second direction; and
a third semiconductor structure located in the fifth sub-portion and extending along the second direction.

10. The sub-pixel structure of claim 9, wherein the first wire layer comprises:
a capacitor first plate located in the first sub-portion, wherein a perpendicular projection of the capacitor first plate on the semiconductor layer overlaps the first semiconductor structure;
a reference voltage line extending along the first direction, connected to the fourth sub-portion and supplying a reference voltage to the at least one switch transistor located within the fourth sub-portion; and
an auxiliary power line extending along the first direction, connected to the fifth sub-portion and supplying a power signal to the at least one switch transistor located within the fifth sub-portion.

11. The sub-pixel structure of claim 10, wherein the second wire layer comprises:
a capacitor second plate located in the first sub-portion, wherein a perpendicular projection of the capacitor second plate on the first wire layer overlaps the capacitor first plate, and an overlapping position forms the storage capacitor; and
a bottom gate located in the second sub-portion, wherein a perpendicular projection of the bottom gate on the semiconductor layer overlaps the second semiconductor structure, and the overlapping position is defined as the drive transistor.

12. The sub-pixel structure of claim 11, wherein the gate layer comprises:
a second scan line extending along the first direction and connected to the third sub-portion, wherein a perpendicular projection of the second scan line on the semiconductor layer overlaps the first semiconductor structure, and the overlapping position is defined as one of the at least one switch transistor located in the third sub-portion;
a first light emission control line extending along the first direction and connected to the third sub-portion, wherein a perpendicular projection of the first light emission control line on the semiconductor layer overlaps the first semiconductor structure, and the overlapping position is defined as one of the at least one switch transistor located in the third sub-portion;
a top gate located in the second sub-portion, wherein a perpendicular projection of the top gate on the semiconductor layer overlaps the second semiconductor structure, and the overlapping position is defined as the drive transistor;
a first scan line extending along the first direction and connected to the fourth sub-portion and the second sub-portion, wherein a perpendicular projection of the first scan line on the semiconductor layer overlaps the first semiconductor structure, and the overlapping position is defined as one of the at least one switch transistor located in the fourth sub-portion; the perpendicular projection of the first scan line on the semiconductor layer further overlaps the second semiconductor structure, and the overlapping position is defined as one of the at least one switch transistor located in the second sub-portion; and
a second light emission control line extending along the first direction and connected to the fifth sub-portion, wherein a perpendicular projection of the second light emission control line on the semiconductor layer overlaps the third semiconductor structure, and the overlapping position is defined as one of the at least one switch transistor located in the fifth sub-portion.

13. The sub-pixel structure of claim 9, wherein the third wire layer comprises:
a data line extending along the second direction, connected to the third sub-portion and supplying a data signal to the at least one switch transistor located in the third sub-portion, wherein a perpendicular projection of the data line on the semiconductor layer is located on an outer side of the first semiconductor structure;
a power line extending along the second direction, connected to the fifth sub-portion and supplying a power signal to the at least one switch transistor located in the fifth sub-portion, wherein a perpendicular projection of the power line on the semiconductor layer is located on an outer side of the third semiconductor structure;
a first jump wire, wherein two ends of the first jump wire are located in the second sub-portion and the third sub-portion respectively, and the first jump wire is configured to connect the drive transistor located within the second sub-portion and the at least one switch transistor located within the third sub-portion;
a second jump wire, wherein the second jump wire is located in the first sub-portion, or two ends of the second jump wire are located in the first sub-portion and the third sub-portion respectively, and the second jump wire is configured to connect the at least one switch transistor located within the third sub-portion and a capacitor second plate located within the first sub-portion;
a third jump wire located in the second sub-portion and configured to connect the drive transistor, the at least one switch transistor and a capacitor first plate that are located within the second sub-portion;
a fourth jump wire, wherein the fourth jump wire is located in the fifth sub-portion, or two ends of the fourth jump wire are located in the second sub-portion and the fifth sub-portion respectively, and the fourth jump wire is configured to connect the at least one switch transistor located within the second sub-portion and the at least one switch transistor located within the fifth sub-portion; and
a fifth jump wire located in the fourth sub-portion and configured to connect the at least one switch transistor and a reference voltage line that are located within the fourth sub-portion.

14. The sub-pixel structure of claim 13, wherein one end of the first jump wire is connected to the drive transistor through a third-type via, and another end of the first jump wire is connected to the at least one switch transistor located within the third sub-portion through the third-type via;
the second jump wire is connected to the at least one switch transistor within the third sub-portion through the third-type via and the second jump wire is connected to the capacitor second plate through a second-type via;
the third jump wire is connected to the drive transistor through a fourth-type via, the third jump wire is connected to the at least one switch transistor within the second sub-portion through the third-type via and the third jump wire is connected to the capacitor first plate through a first-type via;
one end of the fourth jump wire is connected to the at least one switch transistor located within the second sub-portion through the third-type via, and another end of the fourth jump wire is connected to the at least one switch transistor located within the fifth sub-portion through the third-type via;
the fifth jump wire is connected to the at least one switch transistor located within the fourth sub-portion through the third-type via and the fifth jump wire is connected to the reference voltage line through the first-type via; and
the power line is connected to an auxiliary power line located on the first wire layer through the first-type via.

15. The sub-pixel structure of claim 9, further comprising a fourth wire layer located on one side of the third wire layer facing away from the first wire layer, wherein the fourth wire layer comprises:
a second auxiliary power line extending along the second direction, wherein a perpendicular projection of the second auxiliary power line on the semiconductor layer is located on an outer side of the third semiconductor structure;
an auxiliary reference voltage line extending along the second direction and avoiding the first sub-portion; and
an anode jump wire located in at least one of the first sub-portion or the second sub-portion and configured to connect a capacitor second plate and an anode,
wherein the second auxiliary power line is connected to a power line located on the third wire layer through a fifth-type via;
wherein the auxiliary reference voltage line is connected to a fifth jump wire located on the third wire layer through the fifth-type via;
wherein the anode jump wire is connected to a second jump wire located on the third wire layer through the fifth-type via; and
wherein the anode is connected to the anode jump wire through a sixth-type via.

16. The sub-pixel structure of claim 1, wherein a film structure of the sub-pixel structure comprises a first wire layer, a semiconductor layer, a gate layer and a third wire layer, and the first wire layer, the semiconductor layer, the gate layer and the third wire layer are stacked;
two plates of the storage capacitor are disposed on the first wire layer and the gate layer respectively;
an active layer of the drive transistor, a first end and a second end of the drive transistor, an active layers of the at least one switch transistor, a first end of the at least one switch transistor and a second end of an at least one switch transistors are disposed on the semiconductor layer, wherein the first end and the second end of the drive transistor and the first end and the second end of the at least one switch transistor are conductors formed by heavy doping of the semiconductor layer;
a gate of the drive transistor and gates of switch transistors are disposed on the gate layer; and
at least part of connection lines between the drive transistor and the switch transistors, and at least part of connection lines between the switch transistors are disposed on the third wire layer.

17. The sub-pixel structure of claim 16, wherein the semiconductor layer comprises:
a first semiconductor structure extending along the second direction, connected to the third sub-portion and the fourth sub-portion and avoiding the first sub-portion;
a second semiconductor structure located in the second sub-portion and being in a shape of an inverted G, wherein a long side direction of the second semiconductor structure is the second direction; and
a third semiconductor structure located in the fifth sub-portion and extending along the second direction.

18. A display panel, comprising a plurality of sub-pixel structures according claim 1.

19. A preparation method for a display panel, comprising:
dividing a base into a plurality of sub-pixel regions and dividing the plurality of sub-pixel regions into a first sub-portion, a second sub-portion, a third sub-portion, a fourth sub-portion and a fifth sub-portion, wherein the first sub-portion and the second sub-portion are arranged along a first direction; the third sub-portion, the first sub-portion and the fourth sub-portion are arranged sequentially along a second direction; the second direction intersects the first direction; the fifth sub-portion and the fourth sub-portion are parallel in the first direction; and the second sub-portion and the fifth sub-portion are parallel in the second direction; and
forming a storage capacitor within the first sub-portion, forming a drive transistor and at least one switch transistor connected to a control terminal of the drive transistor within the second sub-portion, forming at least one switch transistor connected to a first electrode of the drive transistor within the third sub-portion, forming at least one switch transistor connected to the storage capacitor within the fourth sub-portion, and forming at least one switch transistor connected to a second electrode of the drive transistor within the fifth sub-portion.

20. The preparation method for a display panel of claim 19, wherein a preparation method for the storage capacitor comprises:
forming a first wire layer and patterning the first wire layer to form a capacitor first plate, wherein the capacitor first plate is located in the first sub-portion;
forming a first insulating layer on the first wire layer; and
forming a second wire layer on the first insulating layer and patterning the second wire layer to form a capacitor second plate, wherein the capacitor second plate overlaps the capacitor first plate to form the storage capacitor; and
wherein a preparation method for the drive transistor and switch transistors comprises:
forming a second insulating layer on the second wire layer;
forming a semiconductor layer on the second insulating layer and patterning the semiconductor layer to form a plurality of semiconductor structures;
forming a third insulating layer on the semiconductor layer;
forming a gate layer on the third insulating layer and patterning the gate layer to form gates of the drive transistor and the switch transistors, wherein position at which the drive transistor intersects a semiconductor structures form the drive transistor, and positions at which gates of the switch transistors intersect the semiconductor structures form the switch transistors;
forming a fourth insulating layer on the gate layer;
forming a first-type via at a depth corresponding to a position of the first wire layer and a second-type via at a depth corresponding to a position of the second wire layer;
forming a third-type via at a depth corresponding to a position of the semiconductor layer and a fourth-type via at a depth corresponding to a position of the gate layer; and
forming a third wire layer on the fourth insulating layer and patterning the third wire layer to form a jump wire, a data line and a power line.
